(19) United States
(12) Patent Application Publication
(10) Pub. No.: US 2025/0125174 A1
(43) Pub. Date: Apr. 17, 2025

(54) COOLING STATION

(71) Applicant: SAMSUNG ELECTRONICS CO., LTD., SUWON-SI (KR)

(72) Inventors: Haechul KIM, Suwon-si (KR); Wonjun CHA, Suwon-si (KR); Hyeondong SONG, Suwon-si (KR); Hoyeon JANG, Suwon-si (KR); Minho KIM, Suwon-si (KR)

(21) Appl. No.: 18/830,715

(22) Filed: Sep. 11, 2024

(30) Foreign Application Priority Data
Oct. 12, 2023 (KR) 10-2023-0135694

(51) Int. Cl. H01L 21/673; H01L 21/67

(52) U.S. Cl. CPC H01L 21/6732; H01L 21/67109

(57) ABSTRACT

A cooling station includes: a lower plate; an upper plate spaced apart from the lower plate; a support structure having ends installed on the lower plate and the upper plate, respectively; and a seating member installed on the support structure for a wafer to be seated on the seating member, wherein the seating member has an inclined portion, wherein the wafer is seated on the inclined portion.

### CROSS-REFERENCE TO RELATED APPLICATION

This application claims priority under 35 U.S.C. § 119 to Korean Patent Application No. 10-2023-0135694 filed on Oct. 12, 2023 in the Korean Intellectual Property Office, the disclosure of which is incorporated by reference herein in its entirety.

### TECHNICAL FIELD Example embodiments of the present inventive concept relates to a cooling station.

### DISCUSSION OF THE RELATED ART

In general, after an amorphous carbon layer (ACL) process, a wafer is transferred to a load-lock chamber by a robot and is initially cooled. Thereafter, the wafer is transferred to a cooling station and is cooled.

Here, heat of the wafer is conducted to aluminum hard-anodized and to a slot plate that is provided in the cooling station. Accordingly, aluminum may expand to cause wear and damage to the hard-anodized aluminum, thereby causing aluminum particles. In addition, even the aluminum surface may be ground. In addition, when the temperature of the wafer is lowered while warpage has occurred on the wafer, the wafer may be deformed from its original state and may momentarily stick to the damaged aluminum due to force acting as stress restoration and behavior due to heat conduction. When the wafer is transferred in this state, the wafer may be damaged.

### SUMMARY

According to an example embodiment of the present inventive concept, a cooling station includes: a lower plate; an upper plate spaced apart from the lower plate; a support structure having ends installed on the lower plate and the upper plate, respectively; and a seating member installed on the support structure for a wafer to be seated on the seating member, wherein the seating member has an inclined portion, wherein the wafer is seated on the inclined portion.

According to an example embodiment of the present inventive concept, a cooling station includes: a lower plate; an upper plate spaced apart from the lower plate; a support structure having ends installed on the lower plate and the upper plate, respectively; and a seating member installed on the support structure for a wafer to be seated on the seating member, wherein the wafer is in contact with a line or a point of the seating member.

### BRIEF DESCRIPTION OF DRAWINGS

The above and other aspects of the present inventive concept will become more apparent by describing in detail example embodiments thereof, with reference to the accompanying drawings, in which:

FIG. 1 is a schematic perspective view illustrating a cooling station according to an example embodiment of the present inventive concept;

FIG. 2 is a plan view illustrating a support structure and a seating member of a cooling station according to an example embodiment of the present inventive concept;

FIG. 3 is a side view illustrating a portion of a support structure and a seating member of a cooling station according to an example embodiment of the present inventive concept;

FIG. 4 is a front view illustrating a seating member of a cooling station according to an example embodiment of the present inventive concept;

FIG. 5 is a plan view illustrating a support structure and a seating member of a cooling station according to an example embodiment of the present inventive concept;

FIG. 6 is a side view illustrating a portion of a support structure and a seating member of a cooling station according to an example embodiment of the present inventive concept;

FIG. 7 is a plan view illustrating a support structure and a seating member of a cooling station according to an example embodiment of the present inventive concept; and

FIG. 8 is a side view illustrating a portion of a support structure and a seating member of a cooling station according to an example embodiment of the present inventive concept.

### DETAILED DESCRIPTION OF THE EMBODIMENTS

Hereinafter, example embodiments of the present inventive concept will be described with reference to the accompanying drawings.

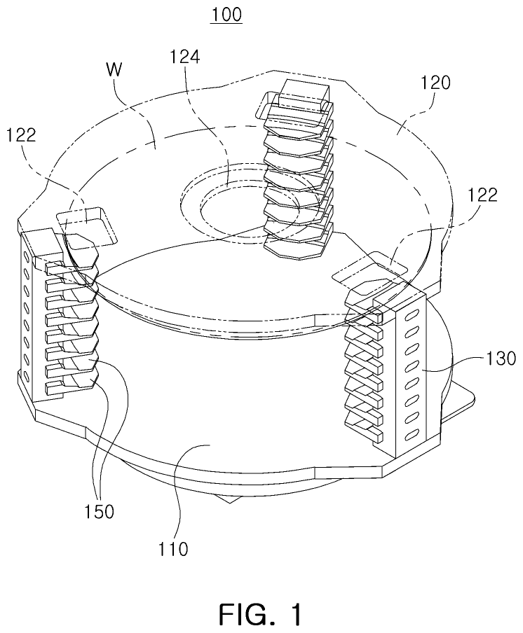

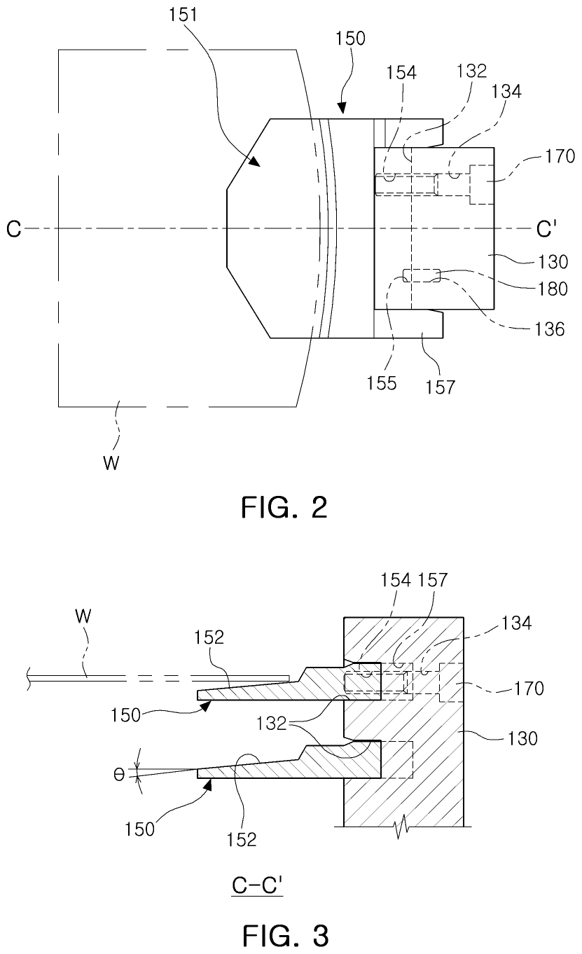

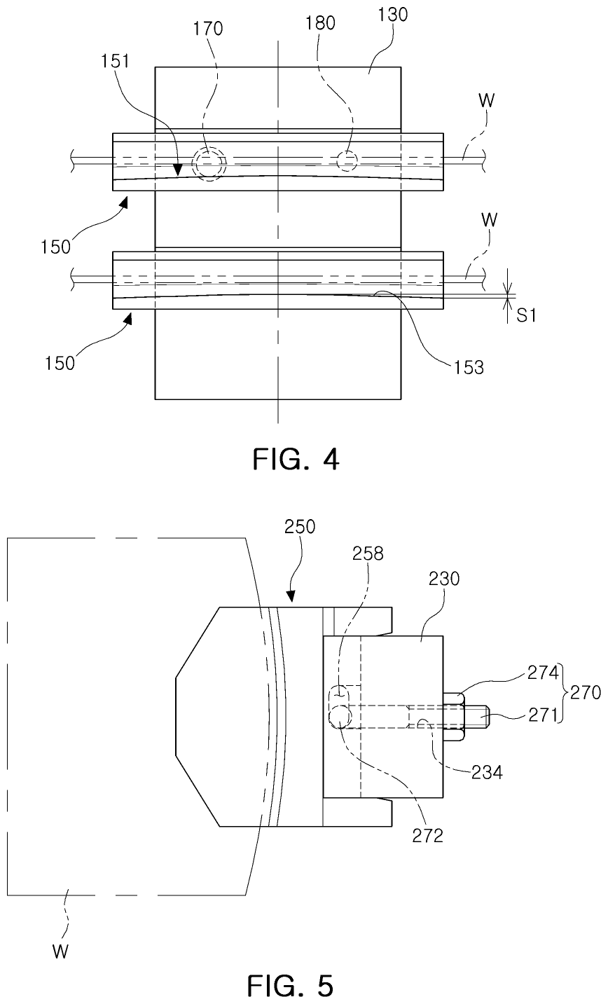

FIG. 1 is a schematic perspective view illustrating a cooling station according to an example embodiment of the present inventive concept. FIG. 2 is a plan view illustrating a support structure and a seating member of a cooling station according to an example embodiment of the present inventive concept. FIG. 3 is a side view illustrating a portion of a support structure and a seating member of a cooling station according to an example embodiment of the present inventive concept, and FIG. 4 is a front view illustrating a seating member of a cooling station according to an example embodiment of the present inventive concept.

Referring to FIGS. 1 to 4, a cooling station 100 according to an example embodiment of the present inventive concept includes a lower plate 110, an upper plate 120, a support structure 130, and a seating member 150.

In addition, the cooling station 100 according to an example embodiment of the present inventive concept may be a cooling station installed in a facility in which an amorphous carbon layer (ACL) process is performed.

The lower plate 110 may have a plate shape, and the support structure 130 may protrude from the lower plate 110. As an example, the lower plate 110 may be fixedly installed in ACL processing equipment. In addition, a size of the lower plate 110 may be larger than a size of a wafer W.

The upper plate 120 may be spaced apart from the lower plate 110 by a predetermined distance. As an example, the upper plate 120 may have a shape corresponding to a shape of the lower plate 110. In addition, the upper plate 120 may have a plate shape, and the support structure 130 may be installed on the upper plate 120. For example, the support structure 130 may be disposed between the lower plate 110 and the upper plate 120. In addition, a size of the upper plate 120 may be larger than the size of the wafer W. As an example, the upper plate 120 may include a transparent window 122 that is disposed on the upper portion of the support structure 130. For example, three transparent windows 122 may be arranged to be spaced apart in a circumferential direction in the upper plate 120. Accordingly, an operator may observe a state in which the wafer W is seated on the seating member 150. In addition, the upper plate 120 may include a central transparent window 124 disposed in the center of the upper plate 120.

Ends of the support structure 130 may be fixed to the lower plate 110 and the upper plate 120, respectively. As an example, three support structures 130 may be arranged to be spaced apart from each other in the circumferential direction. However, without being limited thereto, the number of support structures 130 may vary. In addition, the circumferential direction refers to a rotation direction in a circumferential direction of the wafer.

In addition, a plurality of seating members 150 may be fixedly installed in the support structure 130. As an example, the support structure 130 may include an insertion recess 132 into which the end of the seating member 150 is inserted, as shown in FIGS. 2 and 3. The number of insertion recesses 132 corresponding to the number of seating members 150 may be provided in the support structure 130 in a vertical direction of the support structure 130. In addition, the support structure 130 may include a through-hole 134 that is connected to the insertion recess 132, and a fastening member 170 passes through the through-hole 134. As an example, the through-hole 134 may be arranged to be deflected to one side around the center line C-C′ of the seating member 150 and the support structure 130 when viewed from the top. In addition, the support structure 130 may include a first mounting recess 136 into which an auxiliary fastening member 180, which is disposed to be adjacent to the fastening member 170, is inserted.

The seating member 150 may be fixedly installed on the support structure 130. In addition, the wafer W may be seated on the seating member 150. In addition, the seating member 150 may include an inclined portion 151 (see FIG. 2) in a region in which the wafer W is seated. In addition, the inclined portion 151 may include an inclined surface 152 (see FIG. 3) that is disposed at a front end of the seating member 150 and that is inclined downwardly from a region that comes into contact with the wafer W. In addition, the inclined surface 152 extends toward the center of the wafer W.

In addition, a slope θ of the inclined surface 152 that is shown in FIG. 3 may have an inclination of approximately 3° to approximately 10°. Accordingly, a bottom surface of the wafer W might not contact the inclined surface 152 of the seating member 150, but an edge or bevel of the wafer may contact the inclined surface 152 of the seating member 150. In addition, as shown in FIG. 4, the inclined portion 151 may include a curved surface 153 (see FIG. 4) in which a region, through which the center line C-C′ of the seating member 150 passes, is convex when viewed from above. In addition, a step S1 of the curved surface 153 may be about 0.3 mm to about 1 mm. As an example, the step S1 between the convexly protruding region, through which the center line C-C′ of the seating member 150 passes, and each of edges of the seating member 150 may be about 0.3 mm to about 1 mm. For example, the edges of the seating member 150 may oppose each other. Accordingly, a bottom surface of the wafer W might not contact the curved surface 153 of the seating member 150, but the edge or bevel of the wafer W may contact the curved surface 153 of the seating member 150. In this manner, as the wafer W is seated on the inclined portion 151, the wafer W may be in contact with a line or a point of the seating member 150. Accordingly, a contact area between the wafer W and the seating member 150 may be reduced, thereby reducing heat transferred from the wafer W to the seating member 150.

In addition, the seating member 150 may be formed of a material including a polyimide-based resin. As an example, the seating member 150 may be formed of either PBI (Poly-Benzimidazole (Celazole)) or carbon PEEK (Carbon 30%, polyether ether ketone). Accordingly, a coefficient of thermal expansion and thermal conductivity may be improved compared to the related art in which aluminum is hard-anodized on the seating member 150, thereby preventing the wafer W from being bonded to the seating member 150.

In addition, the seating member 150 may include a screw hole 154 into which a fastening member 170 is coupled such that the seating member 150 is fixedly installed on the support structure 130. After the fastening member 170 passes through the through-hole 134 of the support structure 130 and is coupled to the screw hole 154 of the seating member 150, the seating member 150 may be fixed to the support structure 130. In addition, the seating member 150 may include a second mounting recess 155 disposed to face the first mounting recess 136 of the support structure 130. One end of the auxiliary fastening member 180 may be inserted into the first mounting recess 136 and the remaining portion may be inserted into the second mounting recess 155. As an example, the fastening member 170 may be formed of a wrench bolt, and the auxiliary fastening member 180 may be formed of a pin. In this manner, since the seating member 150 is installed on the support structure 130 through the fastening member 170 and the auxiliary fastening member 180, horizontality or levelness of the seating member 150 may be improved. For example, a tilt in the installation of the seating member 150 may be prevented.

Furthermore, since the auxiliary fastening member 180 is installed in the seating member 150 and the support structure 130, the seating member 150 may be prevented from rotating when the fastening member 170 is coupled to the seating member 150.

In addition, the seating member 150 may include a support portion 157 extending backwardly to be supported on the side of the support structure 130. As an example, the support portion 157 may be inserted into a recess that is provided in the side of the support structure 130. Accordingly, the seating member 150 may be more firmly installed on the support structure 130, and the horizontality or levelness of the seating member 150 may be further improved.

As described above, heat conduction from the wafer W may be reduced through the seating member 150 having the inclined portion 151. In other words, since the wafer W is in contact with a point or line of the seating member 150, heat transfer from the wafer W to the seating member 150 may be reduced.

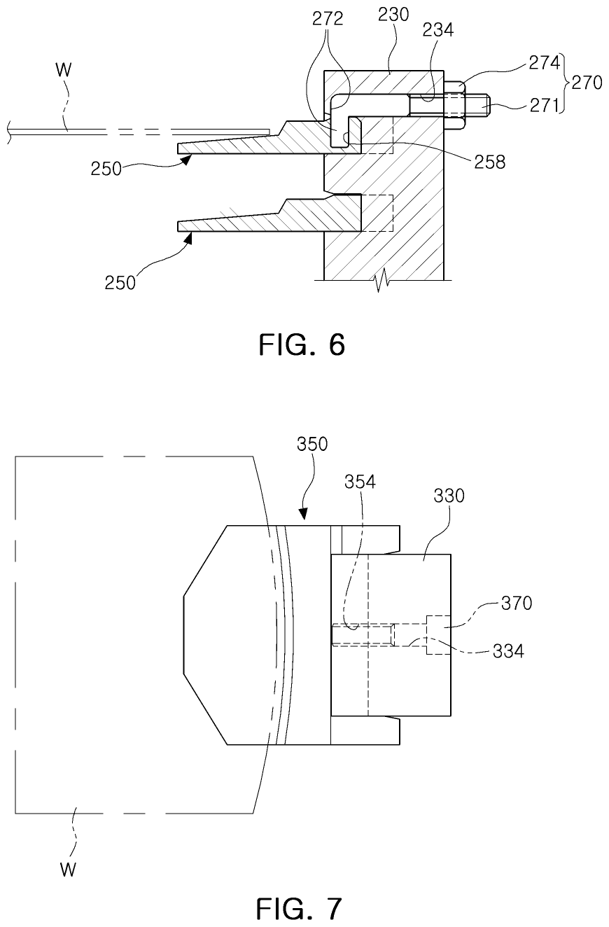

FIG. 5 is a plan view illustrating a support structure and a seating member of a cooling station according to an example embodiment of the present inventive concept, and FIG. 6 is a side view illustrating a portion of a support structure and a seating member of a cooling station according to an example embodiment of the present inventive concept.

Referring to FIGS. 5 and 6, the seating member 250 may be fixedly installed on the support structure 230 through a fastening member 270. In addition, an engaging portion 272 may be inserted into a fixing recess 258, which is formed in the seating member 250, and may be provided at a front end of the fastening member 270. As an example, the fastening member 270 may have an ‘L’ shape. In addition, the support structure 230 may include a through-hole 234 so that the engaging portion 272 may pass therethrough in a horizontal direction. The fastening member 270 may be coupled to the central portion of the seating member 250. Here, referring to an installation method of the fastening member 270, the operator may place the engaging portion 272 of the fastening member 270 in the horizontal direction and then allow a rear end of the fastening member 270 to pass through the through-hole 234. For example, the engaging portion 272 and the fastening member 270 may be inserted through a recess of the support structure 230 prior to the seating member 250 being inserted into the recess of the support structure 230 so that the rear end of the fastening member 270 may pass through the through-hole 234. Thereafter, the seating member 250 may be inserted into the recess of the support structure 230, and the operator may rotate the fastening member 270 by 90 degrees so that the engaging portion 272 faces downwardly. Accordingly, the engaging portion 272 of the fastening member 270 may be inserted into the fixing recess 258 of the seating member 250. Thereafter, the operator may fix the fastening member 270 to the support structure 230 by coupling a nut 274 of the fastening member 270 to a bolt 271 that has the engaging portion 272. Accordingly, the seating member 250 may be pulled toward the support structure 230 and fixed to the support structure 230. Accordingly, the horizontality of the seating member 250 may be maintained, and the seating member 250 may be prevented from being tilted to one side and unevenly worn when the wafer W is seated on the seating member 250.

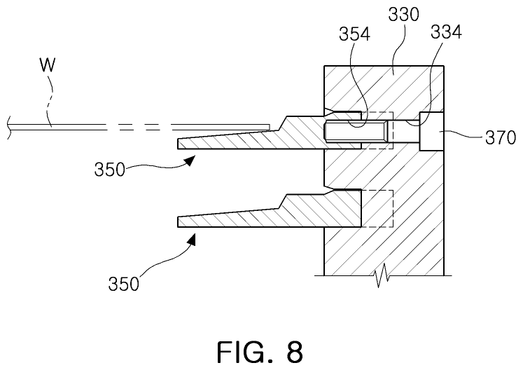

FIG. 7 is a plan view illustrating a support structure and a seating member of a cooling station according to an example embodiment of the present inventive concept, and FIG. 8 is a side view illustrating a portion of a support structure and a seating member of a cooling station according to an example embodiment of the present inventive concept.

Referring to FIGS. 7 and 8, a seating member 350 may include a screw hole 354 into which a fastening member 370 is coupled such that the seating member 350 is fixedly installed on the support structure 330. As the fastening member 370 passes through a through-hole 334 of the support structure 330 and is then coupled to the screw hole 354 of the seating member 350, the seating member 350 may be fixed to the support structure 330. As an example, the fastening member 370 may be formed of a wrench bolt. In addition, the fastening member 370 may be coupled to the central portion of the seating member 350.

The cooling station capable of reducing heat conduction from a wafer may be provided.

While the present inventive concept has been described with reference to embodiments thereof, it will be understood by those of ordinary skill in the art that various changes in form and details may be made thereto without departing from the spirit and scope of the present inventive concept.

What is claimed is:

1. A cooling station comprising:
a lower plate;
an upper plate spaced apart from the lower plate;
a support structure having ends installed on the lower plate and the upper plate, respectively; and
a seating member installed on the support structure for a wafer to be seated on the seating member,
wherein the seating member has an inclined portion, wherein the wafer is seated on the inclined portion.

2. The cooling station of claim 1, wherein the inclined portion includes an inclined surface disposed at a front end of the seating member and inclined downwardly from a region of the seating member toward a center of the lower plate, wherein the region of the seating member is in contact with the wafer.

3. The cooling station of claim 2, wherein the inclined surface has a slope of about 3° to about 10°.

4. The cooling station of claim 3, wherein the wafer is in contact with a line of the seating member.

5. The cooling station of claim 1, wherein the inclined portion includes a curved surface, and a center line of the seating member passes through a convex portion of the curved surface.

6. The cooling station of claim 5, wherein the curved surface has a step difference of about 0.3 mm to about 1 mm.

7. The cooling station of claim 6, wherein the wafer contacts a point of the seating member.

8. The cooling station of claim 1, wherein the support structure and the seating member are coupled to each other by a fastening member that is installed through the support structure.

9. The cooling station of claim 8, further comprising an auxiliary fastening member disposed to be adjacent to the fastening member and fastening the seating member to the support structure.

10. The cooling station of claim 9, wherein the auxiliary fastening member is a pin.

11. The cooling station of claim 1, wherein the seating member includes a polyimide resin.

12. The cooling station of claim 11, wherein the seating member is formed of either PBI (Poly-Benzimidazole (Celazole)) or carbon PEEK (Carbon 30% content, Polyether Ether Ketone).

13. The cooling station of claim 8, wherein a front end of the fastening member includes an engaging portion that is inserted into a fixing recess that is formed in the seating member.

14. The cooling station of claim 13, wherein the support structure includes a through-hole so that a rear end of the fastening member passes therethrough.

15. The cooling station of claim 1, wherein three support structures are arranged to be spaced apart from each other in a circumferential direction between the lower plate and the upper plate.

16. The cooling station of claim 1, wherein the upper plate includes a transparent window that is disposed above the support structure.

17. The cooling station of claim 1, wherein the upper plate includes a central transparent window that is disposed in a center thereof.

18. The cooling station of claim 1, wherein the seating member includes a support portion extending backwardly into a side of the support structure.

19. A cooling station comprising:
a lower plate;
an upper plate spaced apart from the lower plate;
a support structure having ends installed on the lower plate and the upper plate, respectively; and
a seating member installed on the support structure for a wafer to be seated on the seating member,
wherein the wafer is in contact with a line or a point of the seating member.

20. The cooling station of claim 19, wherein the seating member includes at least one of an inclined surface or a curved surface, wherein the inclined surface is inclined downwardly from a region, which contacts the wafer, of the seating member toward a center of the lower plate, and wherein the curved surface includes a convex portion through which a center line of the seating member passes.
